(19) United States
(12) Patent Application Publication
(10) Pub. No.: US 2024/0339548 A1
(43) Pub. Date: Oct. 10, 2024

(54) ANTI-REFLECTIVE NANOSTRUCTURE AND METHOD OF MANUFACTURING THE SAME

(71) Applicant: Korea Advanced Institute of Science And Technology, Daejeon (KR)

(72) Inventors: Jun-Bo YOON, Daejeon (KR); Beom-Jun KIM, Daejeon (KR); Min-Seung JO, Daejeon (KR); Mikiko ITO, Daejeon (KR); Byungkee LEE, Daejeon (KR)

(73) Assignee: Korea Advanced Institute of Science And Technology, Daejeon (KR)

(21) Appl. No.: 18/628,296

(22) Filed: Apr. 5, 2024

(30) Foreign Application Priority Data
Apr. 7, 2023 (KR) 10-2023-0046135
Feb. 8, 2024 (KR) 10-2024-0019324

(51) Int. Cl. H01L 31/0236

(52) U.S. Cl. CPC H01L 31/02363

(57) ABSTRACT

The present disclosure relates to an anti-reflective nanostructure and a method of manufacturing the same, and more particularly, to an anti-reflective nanostructure having a refractive index close to a quintic refractive index profile and exhibiting an anti-reflection effect in which a reflectance is close to almost 0.

The anti-reflective nanostructure according to an embodiment of the present invention includes: a base part having a top surface; and a plurality of nanostructures arranged in a first direction on the top surface and each having a shape in which an upper portion has a thin and sharp shape, a lower portion has a width greater than that of the upper portion, and the width gradually increases in a direction from the upper portion to the lower portion.

### CROSS-REFERENCE TO RELATED APPLICATIONS

This U.S. non-provisional patent application claims priority under 35 U.S.C. § 119 of Korean Patent Application No. 10-2023-0046135, filed on Apr. 7, 2023 and Korean Patent Application No. 10-2024-0019324, filed on Feb. 8, 2024, the entire contents of which are hereby incorporated by reference.

### BACKGROUND

The present disclosure relates to an anti-reflective nanostructure and a method of manufacturing the same, and more particularly, to an anti-reflective nanostructure having a refractive index close to a quintic refractive index profile and exhibiting an anti-reflection effect in which a reflectance is close to almost 0.

Elements such as an optical sensor or solar cell that absorbs light exhibit a high performance because the element absorbs more light as a reflectance of a surface thereof decreases. Also, a lens may transmit more light as a reflectance of a surface thereof decreases.

Since silicon (Si) has a high absorption rate in an ultraviolet rays-visible light range, the silicon is generally used in the elements such as the optical sensor or solar cell. However, the silicon is significantly different from air in that the silicon has a refractive index value of about 3.42 while the air has a refractive index value of about 1. Thus, a silicon film has a high reflectance of about 40% in the visible light range.

An anti-reflective nanostructure has a size less than a wavelength range of specific light and has an effective refractive index (RI) according to a shape of the nanostructure.

FIG. 1 is a view showing an ideal silicon anti-reflective structure and a quintic refractive index profile of the ideal silicon anti-reflective structure.

As illustrated in FIG. 1, since a shape of a structure that exhibits theoretically most excellent anti-reflection effect has a refractive index change rate close to 0 at a boundary at which a medium change, the effective refractive index of the structure has a quintic profile as a curved conic shape having a thin and sharp end.

However, since the ideal silicon anti-reflective structure illustrated in FIG. 1 is substantially difficult to be implemented, a design of the anti-reflective nanostructure capable of exhibiting the anti-reflection effect is required.

### SUMMARY

The present disclosure provides an anti-reflective nanostructure having a refractive index close to a quintic refractive index profile and a method of manufacturing the same.

The present disclosure also provides an anti-reflective nanostructure capable of obtaining an anti-reflection effect in which a reflectance is close to almost 0 and a method of manufacturing the same.

The present disclosure also provides an anti-reflective nanostructure capable of improving photocurrent and sensitivity when applied to a surface of an optical sensor and a method of manufacturing the same.

An embodiment of the present invention provides an anti-reflective nanostructure including: a base part having a top surface; and a plurality of nanostructures arranged in a first direction on the top surface and each having a shape in which an upper portion has a thin and sharp shape, a lower portion has a width greater than that of the upper portion, and the width gradually increases in a direction from the upper portion to the lower portion.

Here, the nanostructure may include: a pillar having a triangular cross-sectional shape; and a protrusion that protrudes from an upper end of the pillar.

Here, the pillar may have a shape extending in a second direction perpendicular to the first direction, the pillar may have a pair of triangular base faces arranged in parallel to the first direction to face each other and rectangular lateral faces disposed between the pair of base faces to extend in the second direction, and the protrusion may have a shape extending in the second direction.

Here, the protrusion may have a width of 30 nm.

Here, the nanostructure may have a reflectance greater than 0 and less than 0.05 for light having a wavelength of 700 nm to 800 nm.

In another embodiment of the present invention, a method for manufacturing an anti-reflective nanostructure includes: a patterning step of patterning photoresist (PR) applied on a silicon substrate to form a PR pattern layer; a reactive ion etching (RIE) step of forming a plurality of nanograting structures or a plurality of nano-pillar structures on the silicon substrate by using a RIE process; a removal step of removing the PR pattern layer disposed on the plurality of nanograting structures or the plurality of nano-pillar structures; and an alkaline etching step of forming a nanostructure by etching the silicon substrate including the plurality of nanograting structures or the plurality of nano-pillar structures, from which the PR patter layer is removed, in a mixed solution of an alkaline solution and isopropyl alcohol (IPA).

Here, a nanostructure may have a shape in which an upper portion has a thin and sharp shape, a lower portion has a width greater than that of the upper portion, and the width gradually increases in a direction from the upper portion to the lower portion.

Here, the alkaline solution may be KOH or tetramethylammonium hydroxide (TMAH) of 1.5 wt % at 65° C.

Here, in the patterning step, a plurality of PR pattern layers may be formed on a top surface of the silicon substrate in a first direction, and each of the PR pattern layers may extend in a second direction perpendicular to the first direction.

Here, in the patterning step, a plurality of PR pattern layers may be formed on a top surface of the silicon substrate in a first direction and a second direction, which are perpendicular to each other.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a view showing an ideal silicon anti-reflective structure and a quintic refractive index profile of the ideal silicon anti-reflective structure;

FIG. 2 is a view for explaining an anti-reflective structure 100 according to an embodiment of the present invention;

FIG. 3 is an enlarged view illustrating a portion of the anti-reflective structure 100 illustrated in FIG. 2;

FIG. 4 is a cross-sectional view obtained by cutting the nanostructure 120 in FIGS. 2 and 3 along a first direction X;

FIG. 5 is a view for explaining a method for manufacturing the anti-reflective nanostructure in FIGS. 2 and 3 according to an embodiment of the present invention;

FIG. 6 shows images for explaining a shape variation of the anti-reflective nanostructure according to an embodiment of the present invention based on a time (hereinafter, referred to as an etching time) in which a silicon substrate is etched in a mixed solution of an alkaline solution and isopropyl alcohol (IPA) illustrated in FIG. 5;

FIG. 7 is a simulation result graph showing a difference in reflectance according to a width (or breadth) of a protrusion 150 illustrated in FIG. 4;

FIG. 8 is an image showing a substantially manufactured anti-reflective nanostructure according to an embodiment of the present invention, which is manufactured by a manufacturing process in FIG. 5;

FIG. 9 is a view for explaining a method for manufacturing an anti-reflection nanostructure according to another embodiment of the present invention;

FIG. 10 is a graph showing a difference in refractive index between a 1-dimensional nanostructure with parabolic cross-section, a 1-dimensional nanostructure with cone cross-section, and the funnel-shaped anti-reflective nanostructure illustrated in FIGS. 2 and 3 according to an embodiment of the present invention;

FIG. 11 is a graph showing a simulation result of reflectances of the 1-dimensional nanostructure with parabolic cross-section, the 1-dimensional nanostructure with cone cross sections, and the funnel-shaped anti-reflective nanostructure illustrated in FIGS. 2 and 3 according to an embodiment of the present invention;

FIG. 12 is a schematic view illustrating an optical sensor including the anti-reflective nanostructure applied to a surface thereof and a SEM image for each surface structure applied to the surface of the optical sensor;

FIG. 13 is a graph obtained by comparing a photocurrent of the optical sensor according to a shape of the surface structure illustrated in FIG. 12;

FIG. 14 is a graph obtained by comparing a sensitivity of the optical sensor according to a shape of the surface structure illustrated in FIG. 12.

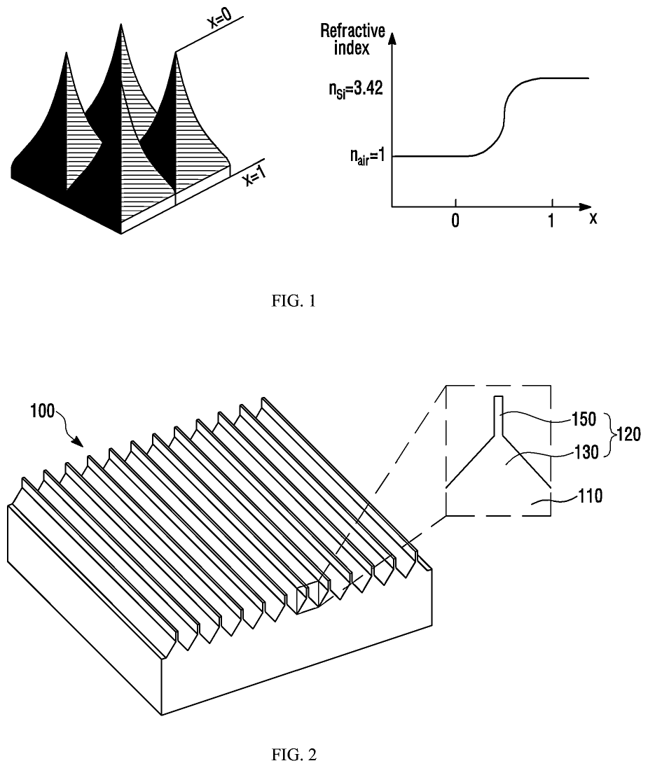

### DETAILED DESCRIPTION

Hereinafter, exemplary embodiments of the inventive concept will be described in detail with reference to the accompanying drawings. It should be noted that like reference numerals refer to like elements throughout. For reference, detailed descriptions related to well-known functions or configurations will be ruled out in order not to unnecessarily obscure subject matters of the present invention.

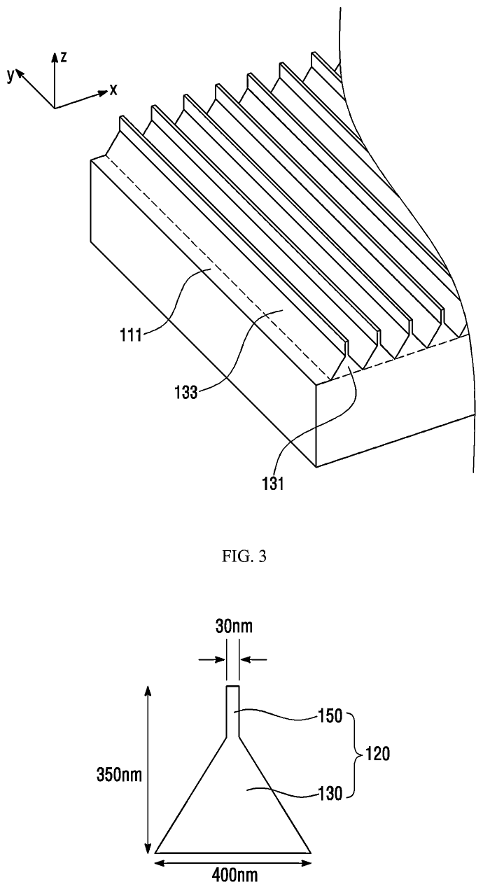

FIG. 2 is a view for explaining an anti-reflective nanostructure 100 according to an embodiment of the present invention, and FIG. 3 is an enlarged view illustrating a portion of the anti-reflective nanostructure 100 illustrated in FIG. 2.

Referring to FIGS. 2 and 3, the anti-reflective nanostructure 100 according to an embodiment of the present invention includes a base part 110 and a nanostructure 120.

The base part 110 has a top surface 111. At least one nanostructure 120 is disposed on the top surface 111.

An upper portion of the nanostructure 120 has a thin and sharp shape.

A lower portion of the nanostructure 120 may have a shape in which a width (or breadth) is greater than that of the upper portion and gradually increases in a downward direction, e.g., a horn shape.

The nanostructure 120 may have a funnel cross-sectional shape.

The nanostructure 120 may include a pillar 130 and a protrusion 150.

The pillars 130 are arranged on a top surface 111 of the base part 110 in parallel along a first direction X. Here, the first direction x may be a direction perpendicular to the second direction y that is a longitudinal direction of the pillar 130.

Each pillar 130 may include a pair of base faces 131 that face each other and three lateral faces 133 disposed between the pair of base faces 131.

The base face 131 has a triangular shape and is parallel to the first direction X.

The lateral face 133 has a rectangular shape extending in the second direction Y that is a longitudinal direction of the pillar 130. One lateral face (not shown) of the three lateral faces 133 is disposed on the top surface 111 of the base part 110.

The pillar 130 may have a triangular cross-sectional shape.

The protrusion 150 has a shape protruding from an upper end of each pillar 130 in the third direction Z. Here, the third direction Z that is perpendicular to each of the first direction X and the second direction Y may be an upward direction when viewed in the drawing. The protrusion 150 has a shape extending in the second direction Y.

The protrusion 150 may have a width in the first direction X, which is gradually constant in a direction from a lower end to an upper end of the protrusion 150 or which gradually decreases in the third direction Z.

When light moves from the air to the anti-reflective nanostructure, the protrusion 150 may minimize a variation of a refractive index, and the pillar 130 may make the variation of the refractive index in the anti-reflective nanostructure similarly to a quintic profile.

The base part 110 and the nanostructure 120 may be made of the same material and integrated with each other. For example, the base portion 110 and the nanostructure 120 may be made of silicon.

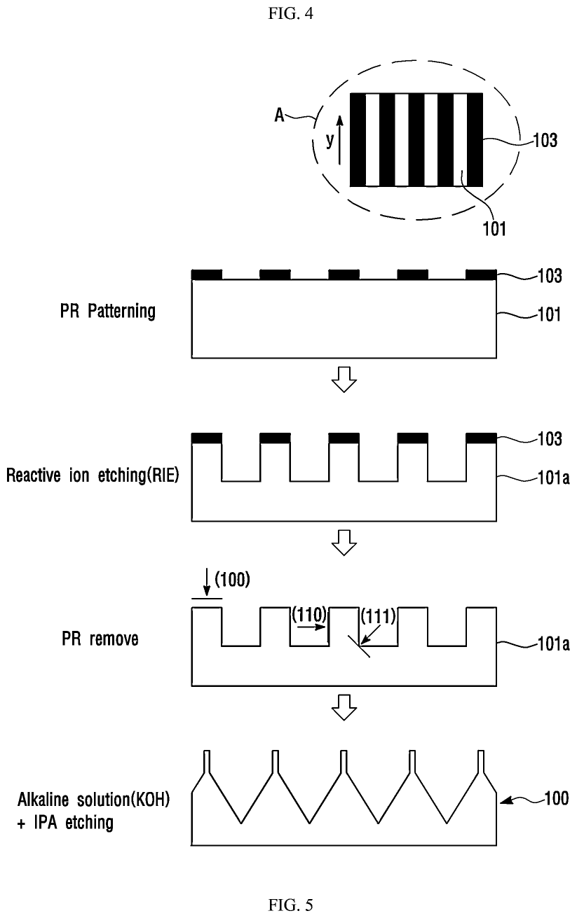

FIG. 4 is a cross-sectional view obtained by cutting the nanostructure 120 in FIGS. 2 and 3 along the first direction X.

Referring to FIG. 4, the nanostructure 120 has a funnel cross-sectional shape. The pillar 130 may have a width in the first direction X, which is greater than a length (or height) of each of the pillar 130 and the protrusion 150 in the third direction Z. For example, the pillar 130 may have a width of about 400 nm, and each of the pillar 130 and the protrusion 150 may have a length of about 350 nm. Here, the protrusion 150 may have a width of about 30 nm or less in the first direction.

FIG. 5 is a view for explaining a method for manufacturing the anti-reflective nanostructure in FIGS. 2 and 3 according to an embodiment of the present invention.

The anti-reflective nanostructure in FIGS. 2 and 3 according to an embodiment of the present invention may be made of a silicon single crystal through a reactive ion etching (RIE) and alkaline etching process.

Since silicon easily absorbs visible light and ultraviolet light, the anti-reflective nanostructure made of the silicon may be applied to an optical sensor.

Referring to FIG. 5, a photoresist (PR) is applied on a silicon substrate 101 and then patterned to form a PR pattern layer 103 (PR patterning). Referring to a plan view A illustrated at an upper end of FIG. 5, each PR pattern layer 103 may have a shape extending in the second direction Y.

Thereafter, a silicon substrate 101 on which a plurality of nanograting structures 101a are formed is formed by using a reactive ion etching (RIE) process (Reactive ion etching).

A size of the anti-reflective nanostructure 100 that is a final product may be adjusted according to a pattern size of the PR layer 103 and a depth of the RIE. Since the size of the optimized anti-reflective nanostructure 100 is varied depending on a frequency of light, the optimized anti-reflective nanostructures 100 according to a wavelength of light may be manufactured by adjusting the pattern size of the PR layer 103 and the depth of the RIE.

Thereafter, the PR pattern layer 103 disposed on the plurality of nanograting structures 101 is removed (PR remove).

Thereafter, a concentration and a temperature of an alkaline solution are adjusted to perform etching at a nanometer level, and then the silicon substrate including the plurality of nanograting structures 101a is etched in a mixed solution of the alkaline solution and isopropyl alcohol (IPA) for a predetermined time (Alkaline solution & IPA etching). Here, the alkaline solution may be a KOH solution of 1.5 wt % at 65° C. Alternatively, the alkaline solution may be tetramethylammonium hydroxide (TMAH).

According to the above-described etching process, since (100) and (110) crystal planes are etched in the nanograting structure 101a instead of a (111) crystal plane, the anti-reflective nanostructure 100 illustrated in FIGS. 2 and 3 may be manufactured.

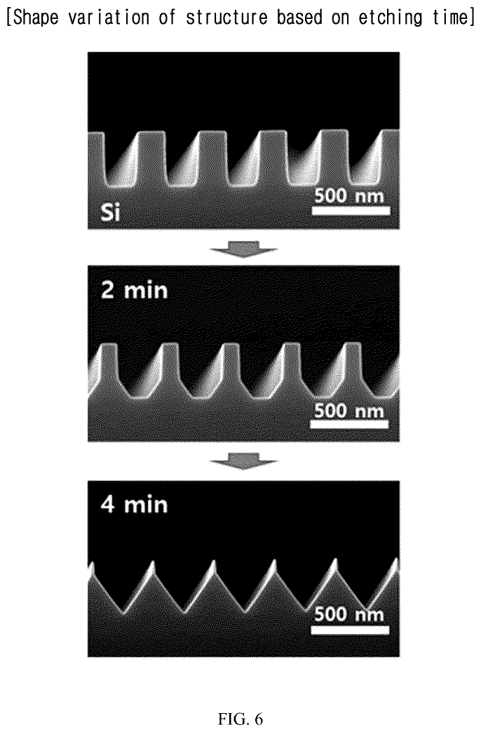

FIG. 6 shows images for explaining a shape variation of the anti-reflective nanostructure according to an embodiment of the present invention based on a time (hereinafter, referred to as an etching time) in which the silicon substrate is etched in a mixed solution of the alkaline solution and the IPA illustrated in FIG. 5.

Referring to FIG. 6, the width (or breadth) of the funnel-shaped nanostructure 120 illustrated in FIG. 4 may be adjusted based on the etching time in which the silicon substrate is etched in the mixed solution of the alkaline solution and the IPA. When the etching time elapses by two minutes, the nanostructure 120 may have a shape similar to that of the funnel-shaped nanostructure 120 illustrated in FIG. 4 when the etching time elapses by two minutes and have the almost same shape as that of the funnel-shaped nanostructures 120 illustrated in FIG. 4 when the etching time elapses by four minutes.

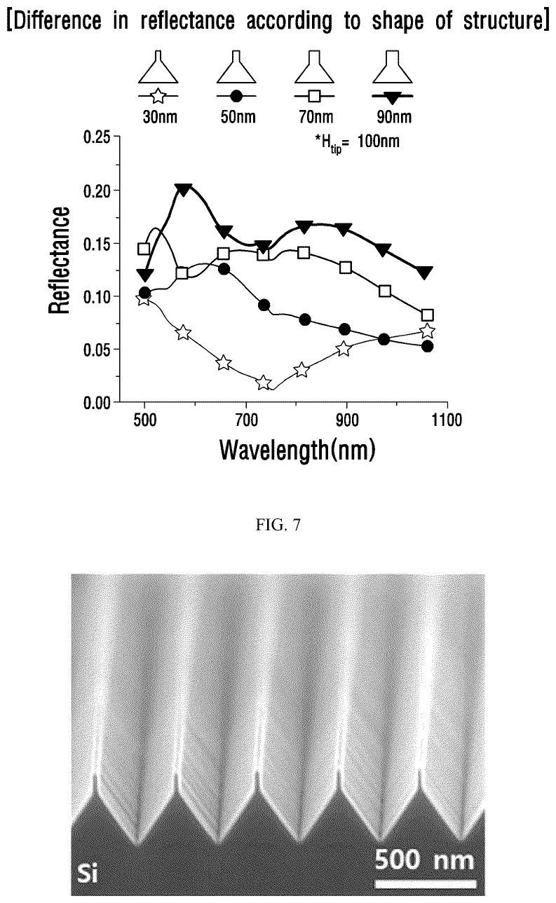

FIG. 7 is a simulation result graph showing a difference in reflectance according to a width (or breadth) of the protrusion 150 illustrated in FIG. 4.

Referring to FIG. 7, the width (or breadth) of the protrusion 150 may be in a range from 20 nm to 30 nm because a refractive index variation is minimized when a medium is varied in the above-described numerical range, and thus the protrusion 150 has a lowest reflectance. More preferably, a reflectance may be minimized in a predetermined wavelength band when the width (or breadth) of the protrusion 150 is 30 nm.

The nanostructure 120 has a reflectance greater than 0 and less than 0.05 for light in a wavelength band of 700 nm to 800 nm.

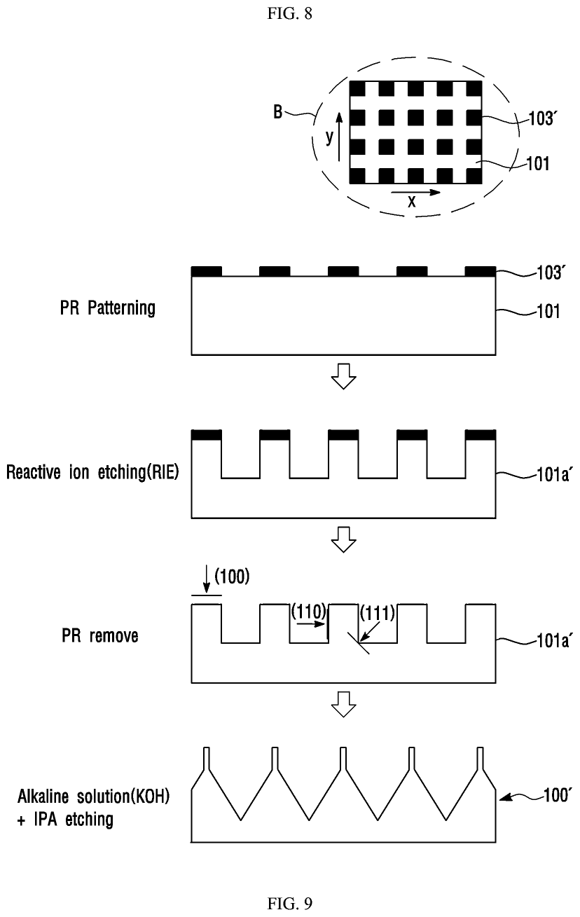

FIG. 8 is an image showing a substantially manufactured anti-reflective nanostructure according to an embodiment of the present invention, which is manufactured by the manufacturing process in FIG. 5.

FIG. 9 is a view for explaining a method for manufacturing an anti-reflective nanostructure according to another embodiment of the present invention.

The manufacturing method of FIG. 9 is different from that of FIG. 5 in a PR patterning process for forming a PR pattern layer 103′. Accordingly, when a RIE process is performed, a plurality of nano-pillar structures 101a′ are formed.

In the PR patterning process illustrated in FIG. 9, the PR pattern layer 103′ having a shape different from that of the PR pattern layer 103 in FIG. 5 is formed. As illustrated in a plan view B illustrated at an upper end of FIG. 9, the PR pattern layer 103′ has a rectangular shape, and a plurality of PR pattern layers 103′ are arranged in the first direction X and the second direction Y.

Here, distances between the plurality of PR pattern layers 103′ in the first direction X and the second direction Y may be constant or adjusted suitable depending on a design.

When the RIE process is performed on a silicon layer 101 on which the PR pattern layer 103′ is formed, the plurality of nano-pillar structures 101a′ are formed. Thereafter, when the PR pattern layer 103′ disposed on the plurality of nano-pillar structures 101a′ is removed, and the plurality of nano-pillar structures 101a′ are etched by using an alkaline solution and an IPA solution, an anti-reflective nanostructure 100′ according to another embodiment of the present invention may be manufactured.

The anti-reflective nanostructure 100′ manufactured as described above may have a zero-dimensional (0D) structure instead of a one-dimensional (1D) structure of the anti-reflective nanostructure illustrated in FIGS. 2 and 3.

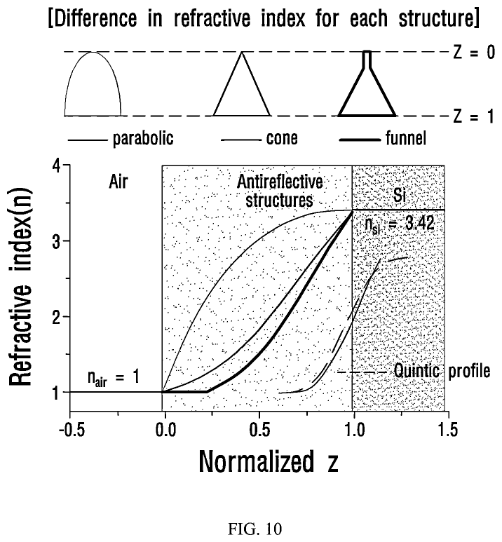

FIG. 10 is a graph showing a difference in refractive index between a 1-dimensional nanostructure with parabolic cross-section, a 1-dimensional nanostructure with cone cross-section, and the funnel-shaped anti-reflective nanostructure illustrated in FIGS. 2 and 3 according to an embodiment of the present invention.

Referring to FIG. 10, it may be observed that the refractive index of the funnel-shaped anti-reflective nanostructure according to an embodiment of the present invention is theoretically similar to the theoretically well-known quintic profile.

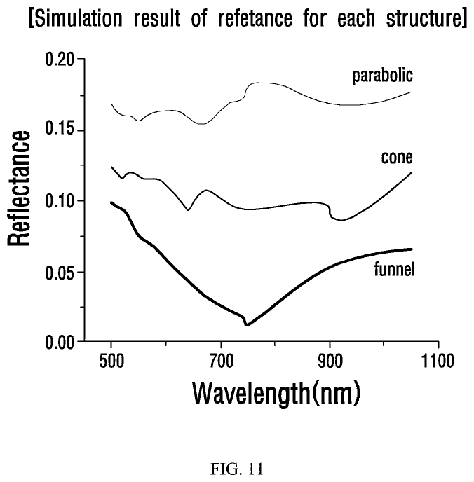

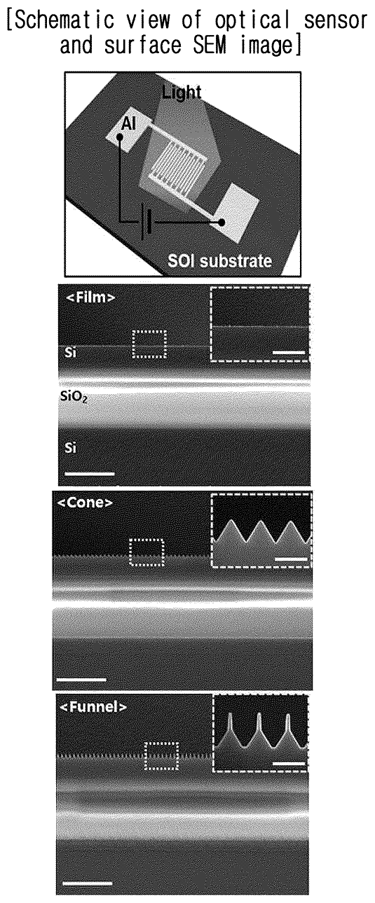

FIG. 11 is a graph showing a simulation result of reflectances of the 1-dimensional nanostructure with parabolic cross-section, the 1-dimensional nanostructure with cone cross-section, and the funnel-shaped anti-reflective nanostructure illustrated in FIGS. 2 and 3 according to an embodiment of the present invention.

Referring to FIG. 11, it may be known even in the simulation result that the funnel-shaped anti-reflective nanostructure illustrated in FIGS. 2 and 3 according to an embodiment of the present invention has the lowest reflectance compared to other anti-reflective nanostructures with the cross-sections. Particularly, it may be observed that the reflectance of the funnel-shaped anti-reflective nanostructures according to an embodiment of the present invention is about 0.17 times of that of the 1-dimensional nanostructure with cone cross-section.

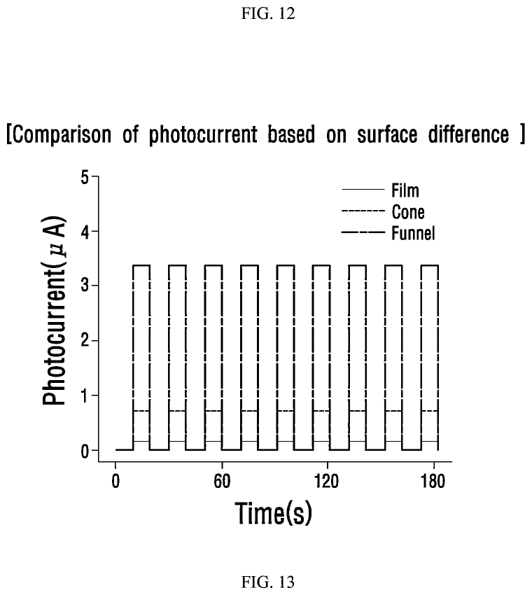

FIG. 12 is a schematic view illustrating an optical sensor including the anti-reflective nanostructure applied to a surface thereof and a SEM image for each surface structure applied to the surface of the optical sensor, and FIG. 13 is a graph obtained by comparing a photocurrent of the optical sensor according to a shape of the surface structure illustrated in FIG. 12.

Referring to FIGS. 12 and 13, it may be known that the photocurrent of the optical sensor including the funnel-shaped anti-reflective nanostructure applied to the surface according to an embodiment of the present invention is about 21 times of that of an optical sensor including a film applied to a surface thereof and about 4.37 times of that of the optical sensor including the 1-dimensional nanostructure with cone cross-section applied to a surface thereof.

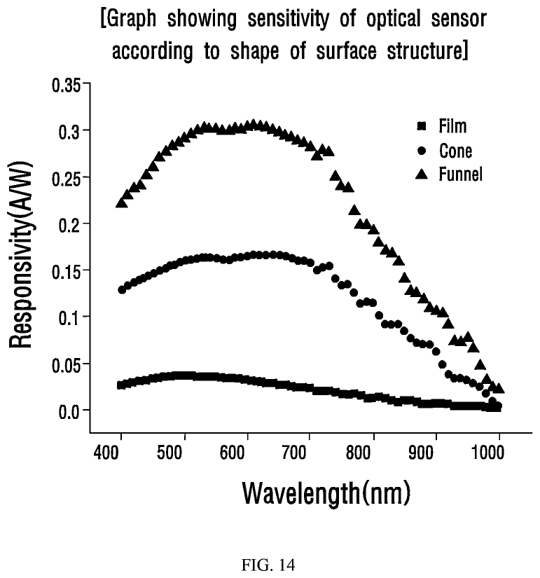

FIG. 14 is a graph obtained by comparing sensitivity of the optical sensor according to a shape of the surface structure illustrated in FIG. 12.

Referring to FIGS. 12 and 14, it may be known that the sensitivity of the optical sensor including the funnel-shaped anti-reflective nanostructure applied to the surface according to an embodiment of the present invention is about 10 times of that of the optical sensor including the film applied to a surface thereof in a predetermined wavelength range (500 nm to 600 nm) and is about two times of that of the optical sensor including the 1-dimensional nanostructure with cone cross-section applied to the surface.

When the anti-reflective nanostructure according to the embodiment of the present invention is used, there is an advantage of having the refractive index close to the quintic refractive index profile.

Also, there is an advantage of obtaining the anti-reflection effect in which the reflectance is close to almost 0.

Also, there is an advantage of improving the photocurrent and the sensitivity when applied to the surface of the optical sensor.

When the anti-reflective nanostructure according to the embodiment of the present invention is used, there is an advantage of manufacturing the anti-reflective nanostructure having the refractive index close to the quintic refractive index profile.

Also, there is an advantage of manufacturing the anti-reflective nanostructure having the anti-reflection effect in which the reflectance is close to almost 0.

Also, there is an advantage of manufacturing the anti-reflective nanostructure capable of improving photocurrent and sensitivity when applied to the surface of the optical sensor and the method of manufacturing the same.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An anti-reflective nanostructure comprising:
a base part having a top surface; and
a plurality of nanostructures arranged in a first direction on the top surface and each having a shape in which an upper portion has a thin and sharp shape, a lower portion has a width greater than that of the upper portion, and the width gradually increases in a direction from the upper portion to the lower portion.

2. The anti-reflective nanostructure of claim 1, wherein the nanostructure comprises:
a pillar having a triangular cross-sectional shape; and
a protrusion that protrudes from an upper end of the pillar.

3. The anti-reflective nanostructure of claim 2, wherein the pillar has a shape extending in a second direction perpendicular to the first direction,
wherein the pillar has a pair of triangular base faces arranged in parallel to the first direction to face each other and rectangular lateral faces disposed between the pair of base faces to extend in the second direction, and
wherein the protrusion has a shape extending in the second direction.

4. The anti-reflective nanostructure of claim 2, wherein the protrusion has a width of 30 nm.

5. The anti-reflective nanostructure of claim 1, wherein the nanostructure has a reflectance greater than 0 and less than 0.05 for light having a wavelength of 700 nm to 800 nm.

6. An optical sensor comprising:
a surface; and
an anti-reflective nanostructure disposed on the surface,
wherein anti-reflective nanostructure comprises:
a base part having a top surface; and
a plurality of nanostructures arranged in a first direction on the top surface and each having a shape in which an upper portion has a thin and sharp shape, a lower portion has a width greater than that of the upper portion, and the width gradually increases in a direction from the upper portion to the lower portion.

7. The optical sensor of claim 6, wherein the nanostructure comprises:
a pillar having a triangular cross-sectional shape; and
a protrusion that protrudes from an upper end of the pillar.

8. The optical sensor of claim 7, wherein the pillar has a shape extending in a second direction perpendicular to the first direction,
wherein the pillar has a pair of triangular base faces arranged in parallel to the first direction to face each other and rectangular lateral faces disposed between the pair of base faces to extend in the second direction, and
wherein the protrusion has a shape extending in the second direction.

9. The optical sensor of claim 7, wherein the protrusion has a width of 30 nm.

10. The optical sensor of claim 6, wherein the nanostructure has a reflectance greater than 0 and less than 0.05 for light having a wavelength of 700 nm to 800 nm.

11. A method for manufacturing an anti-reflective nanostructure, comprising:
a patterning step of patterning photoresist (PR) applied on a silicon substrate to form a PR pattern layer;
a reactive ion etching (RIE) step of forming a plurality of nanograting structures or a plurality of nano-pillar structures on the silicon substrate by using a RIE process;
a removal step of removing the PR pattern layer disposed on the plurality of nanograting structures or the plurality of nano-pillar structures; and
an alkaline etching step of forming a nanostructure by etching the silicon substrate comprising the plurality of nanograting structures or the plurality of nano-pillar structures, from which the PR patter layer is removed, in a mixed solution of an alkaline solution and isopropyl alcohol (IPA).

12. The method of claim 11, wherein a nanostructure has a shape in which an upper portion has a thin and sharp shape, a lower portion has a width greater than that of the upper portion, and the width gradually increases in a direction from the upper portion to the lower portion.

13. The method of claim 11, wherein the alkaline solution is KOH or tetramethylammonium hydroxide (TMAH) of 1.5 wt % at 65° C.

14. The method of claim 11, wherein in the patterning step, a plurality of PR pattern layers is formed on a top surface of the silicon substrate in a first direction, and
each of the PR pattern layers extends in a second direction perpendicular to the first direction.

15. The method of claim 11, wherein in the patterning step, a plurality of PR pattern layers is formed on a top surface of the silicon substrate in a first direction and a second direction, which are perpendicular to each other.
